(19) United States
(12) Patent Application Publication
(10) Pub. No.: US 2024/0255858 A1
(43) Pub. Date: Aug. 1, 2024

(54) IN SITU SENSOR AND LOGIC FOR PROCESS CONTROL

(71) Applicant: Lam Research Corporation, Fremont, CA (US)

(72) Inventors: Ye Feng, Portland, OR (US); Yan Zhang, Fremont, CA (US); Jorge Luque, Redwood City, CA (US)

(21) Appl. No.: 18/565,481

(22) PCT Filed: May 23, 2022
(86) PCT No.: PCT/US2022/030527

§ 371 Date: Nov. 29, 2023

Related U.S. Application Data
(60) Provisional application No. 63/202,214, filed on Jun. 1, 2021.

(51) Int. Cl. G03F 7/00

(52) U.S. Cl. CPC G03F 7/706841; G03F 7/70504; G03F 7/70625

(57) ABSTRACT

A machine learning model may employ in situ chemical composition information, as an input, to characterize processes in real time, and optionally assist in process control. Chemical composition information may be obtained from an in situ emission spectrometer such an optical emission spectrometer.

### INCORPORATION BY REFERENCE

A PCT Request Form is filed concurrently with this specification as part of the present application. Each application that the present application claim benefit of or priority to as identified in the concurrently filed PCT Request Form is incorporated by reference herein in its entirety and for all purposes.

### BACKGROUND

High performance plasma-assisted etch processes are important to the success of many semiconductor processing workflows. However, monitoring, controlling, and/or optimizing the etch processes can be difficult and time-consuming, oftentimes involving process engineers laboriously testing etch process parameters to empirically determine settings that produce a target etch profile. Additionally, in situ monitoring of etch processes can be unreliable; etch endpoint detection remains a challenge.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Some aspects of the disclosure pertain to methods of producing a machine learning model, which methods may be characterized by the following operations: (a) receiving a first training set generated from a first set of wafers, the first training set comprising (i) ex situ metrology data or wafer structure parameter values, obtained from the first set of wafers after the first set of wafers has been processed, and (ii) in situ wafer-level, optical sensor data obtained from the first set of wafers while the first set of wafers was being processed; (b) training a first machine learning model using the first training set, wherein the first machine learning model is configured to receive in situ wafer-level optical sensor data generated from a wafer undergoing processing and predict wafer structure parameter values; (c) using the first machine learning model to generate predicted wafer structure parameter values for a second set of wafers, wherein the second set of wafers has associated in situ chemical composition data and associated in situ wafer-level optical sensor data obtained while the second set of wafers was being processed; and (d) training a second machine learning model using a second training set comprising (i) the predicted wafer structure parameter values from (c), and (ii) the associated in situ chemical composition data obtained while the second set of wafers was being processed, wherein the second machine learning model is configured to receive in situ chemical composition data for a process wafer being processed and predict wafer structure parameter values of the process wafer at one or more times while the process wafer is being processed or after processing is completed. In some embodiments, the wafers of the first set of wafers do not have associated chemical composition data. In some embodiments, the second set of wafers does not have associated ex situ metrology data or wafer structure parameter values.

In some embodiments, the ex situ metrology data is obtained from one or more standalone metrology tools such as a CD-SAXS tool, a CD-SEM tool, or an optical metrology tool.

In some embodiments, the in situ wafer-level optical sensor data includes optical intensity values at multiple wavelengths and multiple times. In some embodiments, the in situ chemical composition data obtained while the second set of wafers was being processed is generated from an optical emission spectrometer.

In some embodiments, the first set of wafers include pilot wafers. In some implementations, the first set of wafers was processed by an etch process. In some embodiments, the second set of wafers include production wafers. In some implementations, the first set of wafers and second set of wafers was processed using the same type of fabrication tool. In some cases, the second machine learning model is configured to predict the wafer structure parameter values for multiple different fabrications tools, which are all of the same type, in an IC fabrication facility.

In certain embodiments, the first machine learning model is configured to produce a reduced dimensional representation of the in situ wafer-level optical sensor data obtained from the first set of wafers and/or perform feature extraction on in situ wafer-level optical sensor data obtained from the first set of wafers.

In certain embodiments, the first machine learning model is configured to perform principal component analysis or utilizes a neural-network-based autoencoder. In certain embodiments, the second machine learning model is configured to reduce the dimensionality of the in situ chemical composition data and/or perform feature extraction on in situ chemical composition data.

In certain embodiments, the second machine learning model is configured to indicate when an etch process has reached an end point.

In certain embodiments, at least some wafers of the first of wafers are also in the second set of wafers. In certain embodiments, the wafer structure parameter values comprise an etch depth, a critical dimension, a side-wall angle, a repeating feature pitch, a layer thickness, a layer material property, or any combination thereof.

Some aspects of the disclosure pertain to computer program products that include a computer readable medium on which are provided computer executable instructions for producing a machine learning model. The instructions may be configured to: (a) receive a first training set generated from a first set of wafers, the first training set comprising (i) ex situ metrology data or wafer structure parameter values, obtained from the first set of wafers after the first set of wafers has been processed, and (ii) in situ wafer-level, optical sensor data obtained from the first set of wafers while the first set of wafers was being processed; (b) train a first machine learning model using the first training set, wherein the first machine learning model is configured to receive in situ wafer-level optical sensor data generated from a wafer undergoing processing and predict wafer structure parameter values; (c) use the first machine learning model to generate predicted wafer structure parameter values for a second set of wafers, wherein the second set of wafers has associated in situ chemical composition data and associated in situ wafer-level optical sensor data obtained while the second set of wafers was being processed; and (d) train a second machine learning model using a second training set comprising (i) the predicted wafer structure parameter values from (c), and (ii) the associated in situ chemical composition data obtained while the second set of wafers was being processed, wherein the second machine learning model is configured to receive in situ chemical composition data for a process wafer being processed and predict wafer structure parameter values of the process wafer at one or more times while the process wafer is being processed or after processing is completed. In certain embodiments, the wafers of the first set of wafers do not have associated chemical composition data. In some embodiments, the second set of wafers does not have associated ex situ metrology data or wafer structure parameter values. In some cases, at least some wafers of the first of wafers are also in the second set of wafers.

In certain embodiments, the ex situ metrology data is obtained from one or more standalone metrology tools. As examples, the standalone metrology tool may be a CD-SAXS tool, a CD-SEM tool, or an optical metrology tool.

In certain embodiments, the in situ wafer-level optical sensor data includes optical intensity values at multiple wavelengths and multiple times. In some embodiments, the in situ chemical composition data obtained while the second set of wafers was being processed is generated from an optical emission spectrometer.

In certain embodiments, the first set of wafers are pilot wafers. In some cases, the first set of wafers was processed by an etch process. In certain embodiments, the second set of wafers are production wafers.

In certain embodiments, the first set of wafers and second set of wafers was processed using the same type of fabrication tool. In some cases, the second machine learning model is configured to predict the wafer structure parameter values for multiple different fabrications tools, which are all of the same type, in an IC fabrication facility.

In some embodiments, the first machine learning model is configured to produce a reduced dimensional representation of the in situ wafer-level optical sensor data obtained from the first set of wafers and/or perform feature extraction on in situ wafer-level optical sensor data obtained from the first set of wafers. In certain embodiments, the first machine learning model is configured to perform principal component analysis or utilizes a neural-network-based autoencoder. In certain embodiments, the second machine learning model is configured to reduce the dimensionality of the in situ chemical composition data and/or perform feature extraction on in situ chemical composition data.

In some embodiments, the second machine learning model is configured to indicate when an etch process has reached an end point. In certain embodiments, the wafer structure parameter values comprise an etch depth, a critical dimension, a side-wall angle, a repeating feature pitch, a layer thickness, a layer material property, or any combination thereof.

Some aspects of this disclosure pertain to systems, which may be characterized by the following features: (a) a process chamber comprising a wafer holder, a plasma source, and a sensor for determining in situ chemical composition data obtained while a process wafer is being processed; and (b) a machine learning model configured to receive in situ chemical composition data for a process wafer being processed and predict wafer structure parameter values of the process wafer at one or more times while the process wafer is being processed or after processing is completed.

In certain embodiments, the wafer structure parameter values of the process wafer comprise an etched feature depth, a feature critical dimension, a feature side-wall angle, a repeating feature pitch, or any combination thereof.

In some embodiments, the system additionally includes logic configured to output an end point detection result based at least in part on the wafer structure parameter values of the process wafer.

In certain embodiments, the plasma source is an inductively coupled plasma source or a capacitively coupled plasma source. In certain embodiments, the sensor for determining in situ chemical composition data is an optical emission spectroscopy sensor.

In certain embodiments, the machine learning model is used for multiple process chambers in an IC fabrication facility. In some such embodiments, the system additionally includes logic to provide offsets, on a per process chamber basis, to predictions by the machine learning model of the (i) ex situ metrology data of the process wafer after processing is completed, and/or (ii) one or more wafer structure parameter values of the process wafer at one or more times while the process wafer is being processed.

In certain embodiments, the machine learning model is configured to produce a reduced dimensional representation of the in situ chemical composition data obtained while the process wafer is being processed. In certain embodiments, the machine learning model is configured to perform principal component analysis or utilize a neural-network-based autoencoder.

In some implementations, the machine learning model was trained by a method including: (a) receiving a first training set generated from a first set of wafers, the first training set comprising (i) ex situ metrology data or wafer structure parameter values, obtained from the first set of wafers after the first set of wafers has been processed, and (ii) in situ wafer-level, optical sensor data obtained from the first set of wafers while the first set of wafers was being processed; (b) training a first machine learning model using the first training set, wherein the first machine learning model is configured to receive in situ wafer-level optical sensor data generated from a wafer undergoing processing and predict wafer structure parameter values; (c) using the first machine learning model to generate predicted wafer structure parameter values for a second set of wafers, wherein the second set of wafers has associated in situ chemical composition data and associated in situ wafer-level optical sensor data obtained while the second set of wafers was being processed; and (d) training the machine learning model using a second training set comprising (i) the predicted wafer structure parameter values from (c), and (ii) the associated in situ chemical composition data obtained while the second set of wafers was being processed.

These and other features of the disclosure will be presented in more detail below.

### BRIEF DESCRIPTION OF THE DRAWINGS

FIG. 1 presents a process flow chart for monitoring an etch process and making adjustments if necessary.

FIG. 2 shows a system comprising a trained second machine learning model configured to provide process control feedback (e.g., endpoint control via one or more process chamber knobs).

FIG. 3A is a table showing various sources of data that may be employed to train a machine learning model and then use the trained machine learning model.

FIG. 3B is a schematic diagram of a process for using data sources and a first machine learning model to develop a second machine learning model.

FIG. 3C is a flow chart representing an example training process for generating a second machine learning model, in accordance with certain embodiments.

FIG. 4 is a schematic illustration of a process chamber including an optical emission spectrometer.

FIG. 5 is a schematic view of an example of an in situ spectral reflectometer system

FIG. 6 shows a control module for controlling one or more aspects of a fabrication tool.

### DETAILED DESCRIPTION

### Introduction and Context

Certain aspects of this disclosure pertain to process control of a reactor in which a wafer or other substrate is being processed. Process control involves adjusting or otherwise controlling process conditions in a reactor. Process control may be based on, at least partially, sensed information about conditions within the reactor and/or information about conditions of a wafer undergoing processing in a reactor. An example of such process control is an end point determination for an etch process. An example of the sensed information is chemical species detection in the reactor and/or on the wafer. Certain aspects of the disclosure pertain to process analysis, process or reactor hardware diagnostics, process or reactor hardware design, or other applications that do not necessarily involve process control.

Certain aspects of this disclosure pertain to machine learning models configured to predict (a) a property of a wafer or other substrate undergoing processing or (b) a postprocessing property condition of wafer that has undergone processing. Such machine learning models may be configured to receive sensed information about the chemical composition of the wafer or gas(es) in process chamber while the wafer is undergoing processing. Because the chemical composition information is sensed while the wafer is undergoing processing, the information is sometimes referred to herein as in situ information. The machine learning models may predict a wafer's property or condition (e.g., a wafer structure parameter such as feature depth, side-wall angle, and/or critical dimension) at the time when the chemical composition information is sensed or at a later time. In some embodiments, a machine learning model is configured to predict a wafer structure parameter at multiple future times based on a single reading of chemical information (e.g., the chemical information is provided for a single instant in time). In some embodiments, a machine learning model is configured to predict a wafer structure parameter based on a time varying reading of chemical information.

In some embodiments, a machine learning model is trained using a limited amount postprocessed wafer metrology information. Training a robust machine learning model requires a large data set but, in many settings, quantities of postprocessed wafer metrology data are very limited. For example, integrated circuit fabrication facilities may collect and provide postprocessing wafer metrology data for only a small subset of the wafers that are processed in pilot or commercial runs. And, in some situations, the entity operating a fabrication facility may consider such information proprietary and be otherwise unwilling to share it for purposes of training a machine learning model.

Frequently, however, in situ measurements are available for a relatively large number of wafers, even when corresponding postprocessing ex situ metrology results are not available for many of those wafers. For example, ex situ metrology results may be available for only about 1 to 20% of wafers for which in situ sensed data is available. In other words, the data sets containing in situ sensor results and postprocessing metrology data are asymmetric.

Certain aspects of this disclosure pertain to machine learning models that employ in situ chemical composition information as inputs, to characterize processes in real time, and optionally serve as part of a process control algorithm. Chemical composition information may be obtained from an in situ emission spectrometer such as an optical emission spectrometer.

In some embodiments, a machine learning model trained to use chemical composition data is trained in at least two stages, and the machine configured to receive the chemical composition data is referred to herein as a “second machine learning model.” In some embodiments, second machine learning models are trained using limited amounts of actual post process metrology data. In some embodiments, generating a second machine learning model involves developing and using a “first machine learning” model that relates in situ, on-wafer, optical processing information to wafer surface parameters such as etched feature characteristics and/or to metrology results produced by such features. In certain embodiments, a first machine learning model is trained using (a) in situ wafer level, optical measurements, typically over a time sequence, obtained from a wafer undergoing an integrated circuit fabrication operation and (b) wafer structure parameters or wafer surface metrology results.

A first machine learning model may be used to generate predicted wafer structure parameters or metrology data for wafers that do not have physical metrology data but do have in situ on-wafer optical measurements. The resulting predicted wafer structure parameters or metrology data may be used as training data to train a second machine learning model. The resulting trained second machine learning model may be configured to predict wafer structure parameters values (e.g., feature characteristics such as critical dimension, side-wall angle, or etch depth) at one or more times from input data that includes sensed in situ chemical composition information such as in situ optical emission spectroscopy signals.

In some embodiments, developing a second machine learning model comprises three principal operations: (a) generating a first machine learning model from a data set comprising postprocessing metrology results and in situ wafer level optical measurements (typically time varying), (b) using the first machine learning model to generate predicted structure parameter values or metrology results for wafers that have in situ wafer level optical measurements, and (c) using the predicted structure parameter values or metrology results together with in situ chemical composition information to produce the second machine learning model.

Regardless of how it is trained, a second machine learning model may be used in many ways. For example, it may be used to control a wafer etch process. Fabrication of certain semiconductor devices involves etching features into one or more materials. In various embodiments herein, features are etched in a substrate having dielectric, semiconductor, and/or conductor material on the surface. The material may be a single layer of material or a stack of materials. In some cases, a stack includes alternating layers of material (e.g., silicon nitride and silicon oxide).

The etching processes are often plasma-based etching processes. A feature may be a recess in the surface of a substrate. Features can have many different shapes including, but not limited to, cylinders, rectangles, squares, other polygonal recesses, trenches, etc. Examples of etched features include various gaps, holes or vias, trenches, and the like.

This disclosure describes (1) methods and apparatus for generating second machine learning models for determining the etch depth and/or another parameter characterizing features produced in an fabrication process (such as an etch or deposition process) from a time-dependent optical signal generated in situ, and (2) second machine learning models configured to receive time-dependent chemical signals (which may be optical signals) detected by in situ measurements and use those optical signals to determine the depth and/or other parameter value of features in a substrate undergoing etch. In certain embodiments, the wafer features are periodic or repeating structures, such as those commonly produced for memory. In certain embodiments, a second machine learning model is implemented in an apparatus such that, when it executes, it provides real-time monitoring of an etch or deposition process in an etch or deposition apparatus. In some implementations, the model determines or assists in determining the endpoint of the etch process.

A process that is monitored or controlled as described herein may have various characteristics. For example, the process may be characterized by the type of material or substrate being etched or deposited on. Sensed chemical information input to the second machine learning model typically varies depending on the materials or other features of the substrate that are being processed. The substrate material may be a conductor, a dielectric, a semiconductor, or any combination thereof. Further, the etched material may be monolithic or layered. It may be used to form memory and/or logic devices. Examples of dielectric materials for etching include silicon oxides, silicon nitrides, silicon carbides, oxynitrides, oxycarbides, carbo-nitrides, doped versions of these materials (e.g., doped with boron, phosphorus, etc.), and laminates from any combinations of these materials. Particular examples of materials include stoichiometric and non-stoichiometric formulations of SiO₂, SiN, SiON, SiOC, SiCN, etc. Examples of conductor materials include, but are not limited to, nitrides such as titanium nitride and tantalum nitride and metals such as cobalt, aluminum, ruthenium, hafnium, titanium, tungsten, platinum, iridium, palladium, manganese, nickel, iron, silver, copper, molybdenum, tin, and various alloys, including alloys of these metals. Examples of semiconductor materials include, but are not limited to, doped and undoped silicon, germanium, gallium arsenide, etc. Any of the above conductors, semiconductors, and dielectrics may have a distinct morphology such as polycrystalline, amorphous, single crystal, and/or microcrystalline. Other materials that may be etched include, but not limited to, CoFeB, Ge2Sb2Te2, InSbTe compounds, Ag—Ge—S compounds, and Cu—Te—S compounds. The concept can be extended to materials like NiOx, SrTiOx, perovskite (CaTiO3), PrCAMnO3, PZT (PbZr1-xTixO3), (SrBiTa)O3, and the like.

The apparatus and machine learning models described herein may be employed in any of various processes such processes for etching features in devices or other structures at any technology node. In some embodiments, the etch is used during fabrication in sub 20 nm technology nodes or sub 10 nm technology nodes. Etching can be used in front end of line fabrication procedures and/or back end of line fabrication procedures.

An etch process may be primarily physical (e.g., non-reactive ion bombardment), primarily chemical (e.g., chemical radicals with only small directional bombardment), or any combination thereof. When a chemical etch is included, the chemical reactant may be any one or more of a variety of etchants including, for example, reactants containing fluorocarbons, fluorine, oxygen, chlorine, etc. Example etchants include chlorine (Cl₂), boron trichloride (BCl₃), sulfur hexafluoride (SF₆), nitrogen trifluoride (NF₃), dichlorodifluoromethane (CCl₂F₂), phosphorus trifluoride (PF₃), trifluoromethane (CHF₃), carbonyl fluoride (COF₂), oxygen (O₂), carbon tetrachloride (CCl₄), silicon tetrachloride (SiCl₄), carbon monoxide (CO), nitric oxide (NO), methanol (CH₃OH), ethanol (C₂H₅OH), acetylacetone (C₅H₈O₂), hexafluoroacetylacetone (C₅H₂F₆O₂), thionyl chloride (SOCl₂), thionyl fluoride (SOF₂), acetic acid (CH₃COOH), pyridine (C₅H₅N), formic acid (HCOOH), and combinations thereof. In various embodiments, a combination of these etching reactants is used.

Many types of apparatus are suitable for conducting etch processes that are controlled in accordance with one or more methods and/or apparatus described herein. Examples of such apparatus include inductively coupled plasma reactors and capacitively coupled plasma reactors. In some embodiments, the etch process is coupled with a deposition process (sometimes in a single reactor). Examples of such coupled deposition and etch processes include processes that employ a side-wall protective layer to produce high aspect ratio features. Examples of atomic layer etching processes are described in U.S. Pat. Nos. 8,883,028 and 8,808,561, each of which is incorporated herein by reference in its entirety.

The features being etched using a second machine learning model as disclosed herein may be characterized by any of various geometric parameters, such as etch depth, critical dimension (the width of an unetched portion between side-walls of adjacent etched features), line width (the width of a raised feature between two or more etch regions), pitch (the distance between center points of adjacent parallel lines), space critical dimension (the difference between the pitch and the line width), side-wall angle, and aspect ratio.

### Terminology

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon or other semiconductor wafer during any of many stages of integrated circuit fabrication thereon. A wafer used in the semiconductor device industry typically has a diameter of 200 mm, or 300 mm, or 450 mm. The following detailed description assumes the disclosed embodiments are implemented on a wafer. However, the disclosure is not so limited.

The work piece may be of various shapes, sizes, and materials. The description herein uses the terms “front” and “back” to describe the different sides of a wafer substrate. It is understood that the front side is where most deposition and processing occur and where the semiconductor devices themselves are fabricated. The back side is the opposite side of the wafer, which typically experiences minimal or no processing during fabrication. In addition to semiconductor wafers, other work pieces that may be processed as described herein include printed circuit boards, magnetic recording media, magnetic recording sensors, mirrors, optical elements including pixelated displays, micro-mechanical devices and the like.

A “semiconductor device fabrication operation” or “fabrication operation,” as used herein, is an operation performed during fabrication of semiconductor devices. Typically, the overall fabrication process includes multiple semiconductor device fabrication operations, each performed in its own semiconductor fabrication tool such as a plasma reactor, a thermal reactor, and the like. Categories of semiconductor device fabrication operations include subtractive processes, such as etch processes and planarization processes, and material additive processes, such as deposition processes (e.g., physical vapor deposition, chemical vapor deposition, and atomic layer deposition). A substrate etch process may include processes that etch a mask layer or, more generally, processes that etch any layer of material previously deposited on and/or otherwise residing on a substrate surface. Such etch process may etch a stack of layers in the substrate.

The terms “Manufacturing equipment” and “fabrication tool” refer to equipment in which a manufacturing process takes place. Manufacturing equipment may include a processing chamber in which a wafer or other workpiece resides during processing. Typically, when in use, manufacturing equipment performs one or more semiconductor device fabrication operations.

Examples of manufacturing equipment for semiconductor device fabrication include subtractive process reactors and additive process reactors. Examples of subtractive process reactors include dry etch reactors (e.g., chemical and/or physical etch reactors) and ashers. Examples of additive process reactors include chemical vapor deposition reactors, and atomic layer deposition reactors, physical vapor deposition reactors, and electroplating cells.

In various embodiments, a process reactor or other manufacturing equipment includes a tool for holding a substrate during processing. Such tool is often a pedestal or chuck, and these terms are sometimes used herein as a shorthand for referring to all types of substrate holding or supporting tools that are included in manufacturing equipment. In various embodiments, a process reactor or other manufacturing equipment includes a gas delivery element such as a showerhead and optionally a plasma generator such an RF coil or a capacitor plate.

Wafers or other workpieces that have not have yet processed in a process chamber or other manufacturing equipment under consideration may be referred to as “preprocessed” wafers. Wafers or other workpieces that were previously processed in a process chamber or other manufacturing equipment under consideration may be referred to “postprocessed” wafers. A preprocessed wafer becomes a postprocessed wafer by undergoing processing in a reaction chamber or other fabrication tool. In some embodiments, in situ chemical composition information obtained on wafers undergoing processing is used to determine process control setting on corresponding manufacturing equipment to produce a target structure parameter value on the surface future postprocessed wafer (e.g., feature depth, CD, side-wall angle, or pitch).

Wafer structure parameters refer to parameters of interest that characterize a wafer. They can be predicted (directly or indirectly) from a second machine learning model such as one described herein. They are parameters that can be assessed using metrology. Of interest, spatial variations in wafer structure parameter values may be utilized to adjust, tune, or optimize a process to achieve a target value of one or more wafer structure parameters in postprocessed wafers.

Examples of wafer structure parameters include geometric feature parameters such as feature depth, width, side-wall angle, and overlay, as well as parameters characterizing repeating structures such as critical dimension and pitch. Examples of wafer structure parameters include physical property parameters such as the thickness of one or more layers on a wafer and dispersive properties such as refractive index and extinction coefficient of one or more layers on a wafer.

“Metrology data” as used herein refers to data produced, at least in part, by measuring features of a processed or partially processed substrate, such as a semiconductor wafer comprising partially fabricated integrated circuits. The measurement may be made before, during, or after performing a semiconductor device fabrication operation in a process chamber. In certain embodiments, metrology data is produced by a non-destructive metrology technique, which may be implemented inline in device fabrication flow. In certain embodiments, metrology data is produced using optical metrology (optionally in the UV, visible, and/or IR portions of the spectrum), X-ray metrology (e.g., CD-SAXS), or electron beam metrology (e.g., SEM and CD-SEM) on an etched substrate. In certain embodiments, optical metrology data is produced by performing reflectometry, dome scatterometry, angle-resolved scatterometry, and/or ellipsometry on a processed or partially processed substrate.

Examples of types of optical metrology signals include values of optical intensity for light that has interacted with a substrate surface. Such light may be reflected (e.g., as by specular reflection), scattered, diffracted, refracted, transmitted, etc. by the substrate surface. The optical intensity values may be provided as a function of location with respect to the substrate and/or incident light, light wavelength (e.g., for spectral data), light polarization state, time, and the like.

Metrology signals may contain information about substrate feature composition and/or geometry. Examples of geometry information include location, shape, and/or dimensions of features. Such information is often obtained from measured optical metrology signals by complicated computations such as widely used optical critical dimension (OCD) techniques.

In some embodiments, a metrology system does not employ integrated computational processing capability for determining compositional and/or geometric information about the substrate features. Rather, such metrology systems may simply produce raw or minimally processed optical signals. For example, some such embodiments feed optical signals directly to one or more machine learning models that analyze the signals to determine processing parameters for a subsequent fabrication operation.

In certain embodiments, a metrology tool can determine high-resolution and/or high accuracy information about a postprocessed wafer's structure parameter values. Such metrology tools may be used ex situ and are sometimes deployed as standalone tools. In various implementations, an ex situ metrology tool can determine, with a high degree of resolution, values of the wafer structure parameters over the face of a wafer. Ex situ optical metrology tools may employ a beam spot in the micrometer scale (e.g., 10s of micrometers such in the 40 micrometer scale). Examples, of ex situ metrology tools include various tools available from metrology tool companies such as KLA Corporation, of Milpitas, California, and Onto Innovation of Milpitas, California.

Metrology performed during processing of a wafer is sometimes referred to as in situ metrology or wafer-level metrology. In situ metrology may be conducted using an optical instrument configured to collect optical information from a wafer that is being processed in a reaction chamber. In situ collected optical intensity values may be provided as a function of time. One example of broadband in-situ reflectometry is flash lamp reflectometry (which may be a Lam Spectral Reflectometer™ (LSR)). For more related information on in-situ metrology systems, reference may be made to Lam Research Corporation U.S. Pat. Nos. 6,400,458, and 6,160,621, which are incorporated herein by reference in their entireties.

Chemical composition information may be obtained in situ from a wafer being processed and/or from the reaction chamber where processing is occurring. Various types of in situ chemical composition sensors may be employed. Some chemical composition sensors detect emission signals from chemical or atomic species and some measure absorption by chemical or atomic species. Examples include optical emission spectrometers (OES), residual gas analyzers, IR sensors (including FTIR sensors), Raman spectrometers, and optical absorption-based spectrometers. Sensed information may include broadband information (spectral) or single wavelength data. OES is a broadband emission signal technique, while a Lam Research technique (“Lam Control System” (LCS)) is an example of a single wavelength absorption technique.

In some embodiments, one or more such chemical composition sensors are used in conjunction with one or more other sensors, such V/I probes and/or RF sensors, to provide a more complete representation of in situ conditions. For example, OES and/or one or more other sensors may be employed to characterize plasma density, process gas concentration, and/or byproduct and other gas concentrations. OES sensors may measure emission spectra from plasma and/or gases present in a process chamber.

In OES, an excitation source such a plasma generated in a reaction chamber excites atoms within the chamber, which atoms emit characteristic light, or optical emission lines. In emission spectrometers, an optical system captures light from the atoms and passes the light to a spectrometer, which may be a diffraction grating. A corresponding detector measures the intensity of light for each wavelength. The intensity measured is proportional to the concentration offset element in the sample.

The particular atoms in the chamber, and their associated contribution to emission signals, depend on the state of a wafer undergoing processing. For example, as a wafer is being etched, the composition and flux of chemical or atomic species driven from the wafer may change, and that change causes a corresponding change in the emission signal that may be detected by an OES sensor. A rise in the emission signal of a particular species may correspond, at least roughly, with a particular etch depth on the wafer's surface, which may be due different materials being present at different depths of the wafer.

A “machine learning model” is a trained computational model. A machine learning model may be trained using supervised learning, semi-supervised training, or unsupervised training. In some embodiments herein, a machine learning model is configured to receive as inputs in situ sensor data (which may be provided as a time series) to generate output information that is characteristics of wafer surface parameters such as feature geometries. This output may be employed to achieve real-time process control of the device fabrication tool. Examples of machine learning models include regularized linear models, support vector machines, decision trees, random forest models, gradient boosted trees, neural networks, and autoencoders. Machine learning models are trained using a training set that reflects a range of conditions for which the model should be able to, e.g., accurately control a device fabrication tool (e.g., identify a time at which an etch endpoint occurs).

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on or is not executing).

The components used with the “configured to” language may refer to hardware—for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic, as well as main memory, system memory, and the like.

The disclosed model training and process control embodiments can be implemented in numerous ways, including as a process, an apparatus, a system, a computer program product embodied on a computer readable storage medium, a processor, such as a processor configured to execute instructions stored on and/or provided by a memory coupled to the processor, and any combination thereof. In general, the order of the steps of disclosed processes may be altered within the scope of the disclosure. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

### Process Control

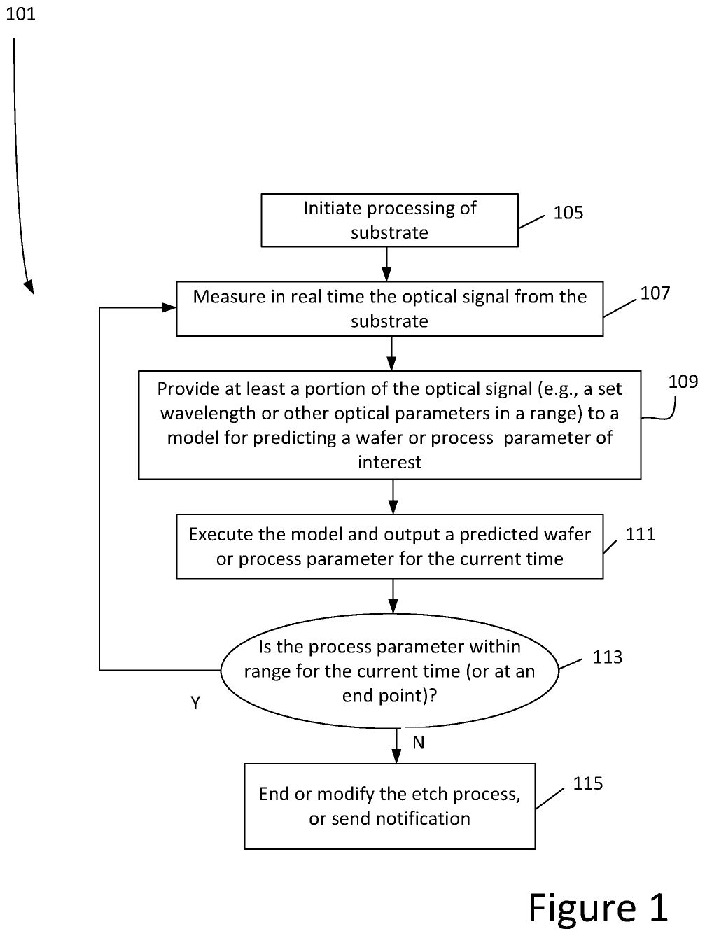

FIG. 1 presents a process 101 for monitoring a fabrication operation and making adjustments if necessary. An in situ monitoring tool (e.g., an OES tool) and/or processors acting on monitoring data may be configured to provide data that may be used directly or indirectly as input for a second machine learning model such as described herein.

After an optional setup is complete, the depicted process initiates the fabrication operation in a fabrication tool as indicated by operation 105. As understood by those of skill in the art, this may involve positioning a substrate in a fabrication tool, evacuating the fabrication tool chamber, flowing process gas into the fabrication tool chamber, striking a plasma, and the like. Initially, in an etch process for example, the substrate may include only a mask or other structure for defining an etch pattern. The underlying material to be etched has not been etched or otherwise affected in any substantial way before the fabrication operation is initiated in operation 105.

As the fabrication operation unfolds, the process environment is monitored in real time using sensed chemical information (e.g., an optical emission or absorption signal) from the substrate or chamber internal environment. See process block 107, which represents the continuing measurement of real-time chemical signals from the substrate. The chemical signals may be provided as in situ optical signals (e.g., intensity values at a set of wavelengths or other optical parameter(s)), appropriate for the current time and optionally prior times as well. The second machine learning model uses these signals for predicting a wafer structure parameter of interest and/or a metrology value. See process block 109. In certain embodiments, the second machine learning model is configured to process only a particular range or other subset of optical parameters (e.g., intensity values at particular wavelengths) at any given time or a range of times during the etch process. Operation 109 may ensure that the model receives the collected parameters, as appropriate, for the current time.

Next, for the current time step, the second machine learning model executes using the input sensed chemical signals and provides a predicted wafer structure parameter or predicted metrology value. This is illustrated at block 111. The second machine learning model may, in addition to calculating parameters in real time, determine whether they are within an expected range or whether they signal an endpoint of the process. This check is illustrated at decision block 113.

Process control returns to block 107, where the in situ monitoring system continues to collect real-time sensed chemical information signals. As described above, while this occurs, the second machine learning model continues to (i) receive sensed chemical signals (operation 109) and (ii) provide predicted wafer structure parameter or predicted metrology parameter for the current time step (operation 111). Additionally, the second machine learning model continues to determine whether the predicted structure parameter is within the expected range at operation 113.

At some point, the evaluation conducted in decision operation 113 results in a negative finding, i.e., the predicted structure parameter or metrology result is outside the expected range or the parameter has reached an endpoint. At that time, process flow is directed to a process operation 115, which modifies or ends the current fabrication operation, or sends a notification to a system which can cause automatic or manual intervention in the fabrication operation. Such intervention may involve further evaluation to determine whether a course adjustment is required and/or whether the process should be terminated. Process termination may be appropriate in the case of end point control, for example.

From the system's perspective, the relevant operations are 109, 111, 113, and 115. If one considers the process flow purely from that perspective, operation 109 involves “receiving at least a portion of the optical signal . . . ,” and the arrow looping back from decision operation 113 goes to block 109, rather than 107.

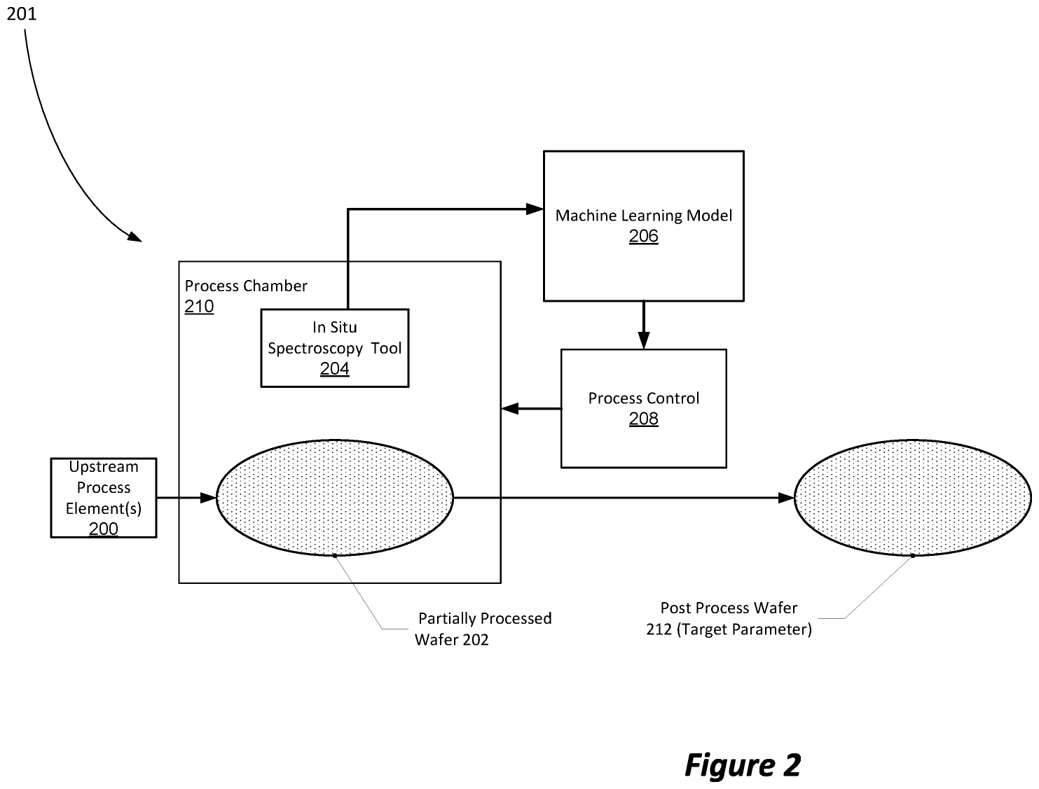

FIG. 2 schematically represents a process system 201 that includes a process chamber 210 in fabrication communication with one or more upstream processing elements 200 such as fabrication tools (e.g., lithography tools, cleaning tools, and/or etch/deposition tools), wafer handling or storing elements, and/or metrology tools. After a wafer is processed or handled by upstream processing elements 200, it is delivered to process chamber 210 where it undergoes a processing such as deposition or etching. While undergoing processing in process chamber 210, the wafer may be viewed as a partially processed wafer 202. And while partially processed wafer 202 undergoes processing in process chamber 210, an in situ chemical information sensing tool 204, such as an OES sensor, receives signals from the wafer or environment in the chamber. In various embodiments, the signals represent or contain chemical composition information such as spectra emitted by products or biproducts of a fabrication operation such as etch or deposition taking place in chamber 210. As illustrated, tool 204 is disposed within (or is otherwise has access to) process chamber 210.

System 201 is configured to transmit signals from tool 204 to a machine learning model 206 (e.g., a second machine learning model as described herein), which is configured to convert or interpret the signals to a representation of a wafer structure parameter value (e.g., etch depth) and/or a metrology result that would be produced if the partially processed wafer was now a postprocessed wafer. System 201 is also configured to transmit output from model 206 to process control logic 208, which is configured to control the operation of process chamber 210 based on (at least partially) the output of model 206. For example, logic 208 may provide instructions to end an etch operation upon receipt of information indicating that features of partially processed wafer 202 have been etched to a threshold depth.

In some embodiments, machine learning model 206 and process control logic 208 are combined in a single logic block. As used herein, “second machine learning model” includes at least logic configured to receive chemical composition information (e.g., OES signals) and output information related to a current state (and/or future state) of the wafer currently undergoing processing.

Upon completion of processing partially processed wafer 202, which processing is conducted under the control of process control logic 208, the wafer leaves process chamber 210 as a post processed wafer 212.

While not depicted in FIG. 2, machine learning model 206 and/or process control logic 208 may be configured to receive, as input, information from upstream process elements 200. Such information may include, for example, upstream metrology information (e.g., preprocessed wafer information), upstream process conditions/settings information for one or more upstream fabrication tools, etc. In such cases, machine learning model 206 and/or process control logic 208 is trained or otherwise configured to interpret such inputs, in addition to the already mentioned input such as chemical composition information from an in situ sensor.

### Training Machine Learning Models

In various embodiments, a training procedure produces a machine learning model configured to (a) accept as input chemical composition information obtained in situ during processing of a wafer in a reaction chamber and (b) output information that predicts a current or a postprocessed state of the wafer undergoing processing. As an example, the state may be associated with a wafer structure parameter value such as an etched feature's depth or critical dimension. The state may also be represented as a postprocessing metrology value. The chemical composition information may be a time series of sensed chemical signals (e.g., emission or absorption signals). The chemical composition information may be spectral or broadband information.

Many reaction chambers have sensors configured to collect in situ chemical composition information (e.g., OES sensors) but do not have sensors for collecting in situ wafer-level, optical information (e.g., reflectometry data). Yet, in situ wafer-level, optical information can be a good predictor of postprocessed wafer properties.

In some embodiments, a training module or process is configured to train a machine learning model (often referred to as a second machine learning model) in a way that leverages available in situ wafer-level optical sensor information to prepare the machine learning model. As indicated, a machine learning model may be configured to receive in situ chemical composition information and output wafer structure parameter values, which may be represented as geometric or material characteristics of a wafer's surface. Leveraging in situ wafer-level optical sensor information for training may greatly reduce the amount ex situ metrology data needed from postprocessed wafers. Leveraging in situ wafer-level optical sensor information may involve producing a first machine learning model that is used to expand the amount of available training data to train a robust second machine learning model.

In certain embodiments, training a second machine learning model is conducted via multiple operations. As an example, consider the following operations.

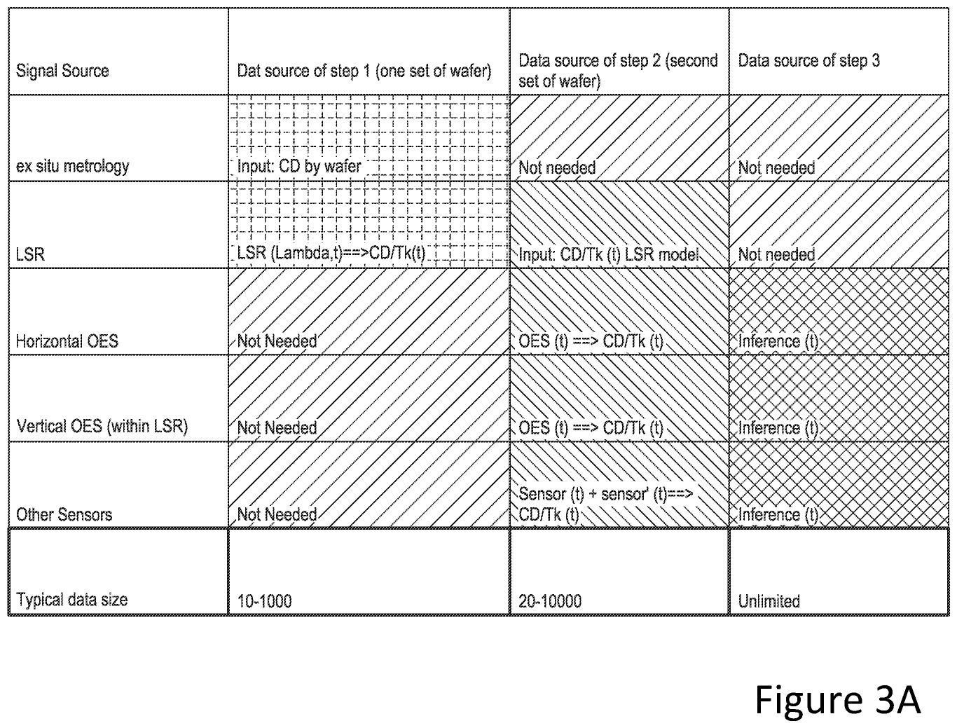

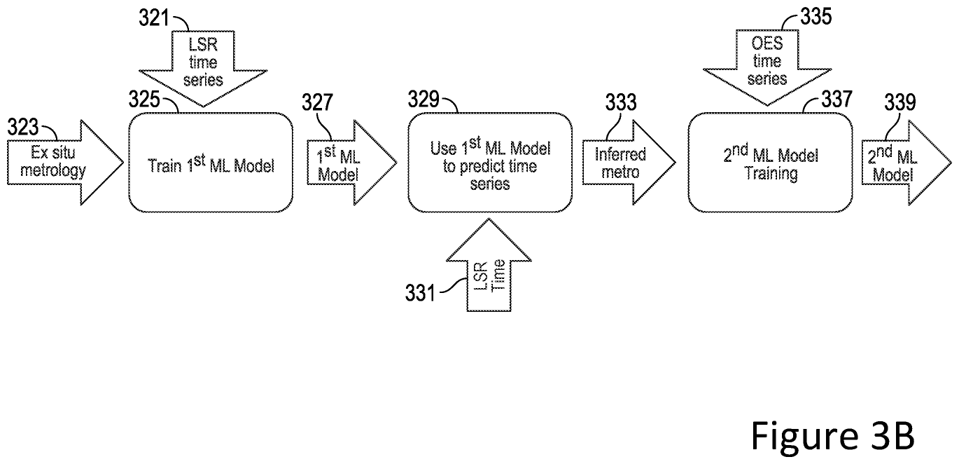

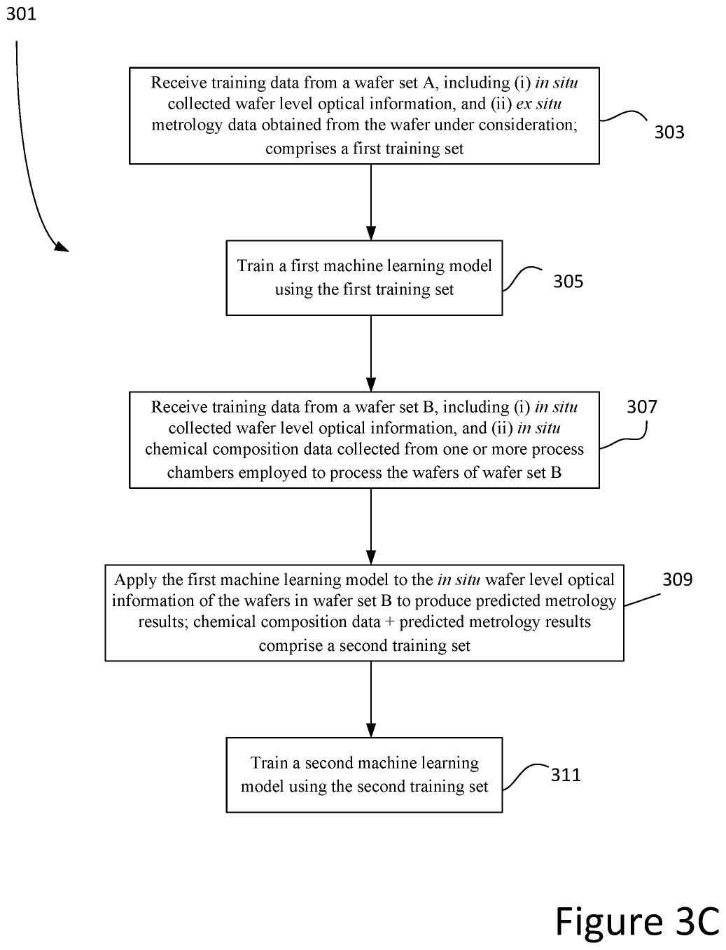

First, using data from wafers having ex situ postprocessed metrology information, a training process trains a first machine learning model that provides a relationship between in situ wafer-level optical sensor signals and postprocessed metrology information. The in situ wafer-level optical sensor signals may be provided as a time series of optical signals. The training employs a first training set that includes a combination of ex situ postprocessed metrology information together with in situ wafer-level, optical sensor signals (e.g., a time series of in situ reflectometry data). The first training set is obtained from a first set of wafers, which are wafers for which both ex situ postprocessed metrology information and in situ wafer-level, optical sensor signals exist. In the non-limiting context of FIG. 3C (described below), this first phase of training may correspond to operations 303 and 305.

Second, using data from wafers undergoing processing that includes both in situ on-wafer reflectometry signals and in situ chemical composition information—but typically not having ex situ postprocessed metrology information—a computational process uses the first machine learning model to predict ex situ metrology information and/or wafer structure parameter values of wafers undergoing processing or postprocessed wafers. In a sense, the first machine learning serves as a tool for generating wafer structure parameter values and/or metrology data on wafers for which actual ex situ metrology data is not available. The first machine learning model can generate predicted metrology results for many wafers that have in situ on-wafer, optical signals but do not have actual postprocessed ex situ metrology results. In this way, inferred ex situ metrology results can be generated for many wafers. In essence, an actual “metrology result” can be substituted with “inferred metrology result.” The result is a large data set having in situ chemical composition information and wafer structure parameter values or ex situ metrology results. In the non-limiting context of FIG. 3C, this second phase of training may correspond to operations 307 and 309. In some cases, both in situ collected reflectometry signals and in situ chemical composition signals are provide as time series, with a pairing of reflectometry and chemical composition signals at multiple time steps.

Third, the training method trains a second machine learning model using a second training set, which comprises (a) a combination of in situ chemical composition information (provided from the wafers used in the second phase of training) and computationally generated (inferred) wafer structure parameter values or metrology information for wafers that did not have actual post-processing wafer metrology information. The second training set also optionally includes a combination of in situ chemical composition information and postprocessing metrology information for wafers that have actual postprocessing wafer metrology information. In the non-limiting context of FIG. 3C, this second phase of training may correspond to operation 311.

Regarding the first operation, relatively few wafers have both ex situ postprocessing metrology information and in situ wafer-level, optical sensor signals information. But the quality of the in situ wafer-level optical information and its direct relation to wafer surface properties provides useful training information for models that predict wafer structure parameter values and/or ex situ postprocessing metrology information. On-wafer, optical sensing typically provides a good predictor of postprocessed wafer surface properties or metrology values. In some contexts, it is a better predictor than chemical composition sensing.

Note that the in situ wafer-level, optical sensor information may comprise detected intensity values at multiple wavelengths and/or over multiple time steps (e.g., intensity versus wavelength versus time). In situ wafer level optical sensor information may be collected using a reflectometer that is disposed within process chamber or that has access to a process chamber via one or more windows. Examples of reflectometers include laser and wideband in situ reflectometers, such as those described herein.

In certain embodiments, in situ wafer-level, optical sensor data is collected over a period of at least about 2 seconds and/or a period of at most about 2000 seconds. In certain embodiments, in situ wafer-level optical sensor data is collected at a frequency of at least about 1 Hz and/or a frequency of at most about 20 Hz. Fast sampling may be appropriate when processes have short process segments such as about 5 seconds or less. This may be the case for certain cyclic processes such as atomic layer deposition (ALD) or atomic layer etch (ALE).

In certain embodiments, the spectral range of the in situ wafer-level, optical sensor data includes at least a fraction of the visible range, at least a fraction of the infrared range, at least a fraction of the ultraviolet range, or any combination thereof.

In certain embodiments, ex situ metrology data is obtained using a metrology tool configured to determine high-resolution and/or high accuracy information about a postprocessed wafer's structure parameter values. Such metrology tools are sometimes standalone tools, although they may be integrated with a reaction chamber. In various implementations, an ex situ metrology tool can determine, with a high degree of resolution, values of the wafer structure parameters over the face of a wafer. Ex situ metrology tools may employ a beam spot size in the micrometer scale (e.g., 10s of micrometers such as about 40 micrometers).

In certain embodiments, a training process trains the first machine learning model using ex situ metrology data from at most about 10 wafers or from at most about 1000 wafers.

In certain embodiments, the in situ and ex situ data in first training set is collected at a common or overlapping location on wafers. The in situ optical, wafer level data may be provided at a first location on the wafer while the wafer is processed, and the ex situ metrology may be collected at the first location (or an overlapping location) on the postprocessed wafer.

In some embodiments, the ex situ data used in the first training set is generated for wafers that have undergone different lengths of processing. That way, different times and/or different wafer conditions at different times are represented in the first training set. For example, a given etch process run to different lengths of time may produce different etch depths, which can be detected by ex situ metrology. Using such training data, the resulting first machine learning model can predict time sequence wafer structure parameter values and/or ex situ metrology values using available in situ metrology information, optionally from different stages (times) in fabrication process. Note also that the in situ data may be collected at many times during processing, including up to near the end of a process under consideration. Thus, a model may employ a time series of in situ measurements as an input or a single in situ measure that is obtained prior to, although possibly very close in time to, the measured ex situ metrology result.

A first machine learning model generated in the first operation may, during execution, produce or operate on a reduced dimensional representation of the in situ wafer-level, optical sensor data. The reduced dimensional representation may be produced by any of various techniques including principal component analysis, an autoencoder, a polynomial representation/fit of the in situ wafer-level optical sensor data, etc.

The raw data provided to a first machine learning model may contain at least three-dimensional information: e.g., radiation intensity values at multiple wavelengths and over multiple time steps. In the first machine learning model, certain principal components or latent dimensions may be extracted and may represent relevant features of the in situ wafer-level, optical sensor data. The feature reduction or extraction associated with training and/or using a first machine learning model may reduce or remove parameters or contributions from parameters that are correlated or highly correlated.

Regarding the second operation, the first machine learning model may be executed repeatedly to greatly expand the data available for training a second machine learning model. In certain embodiments, the first machine learning model generates predicted wafer structure parameter values and/or ex situ metrology data for at least about 20 wafers or for at least about 1000 wafers. These wafers may each include in situ chemical composition information such as optical emission spectroscopy data. In some embodiments, the training operation generates predicted wafer structure or metrology data for only wafers that do not have physically generated ex situ postprocessed metrology information. Predicted wafer structure or metrology data is sometimes referred to as virtual or inferred data. It may be employed in a second training set to train a second machine learning model.

Regarding the third operation, the second machine learning model is trained using in situ chemical composition information and corresponding (typically from the same wafer) wafer structure parameter values and/or ex situ metrology data. Some or all the wafer structure parameter values and/or ex situ metrology training data is inferred, using the first machine learning model, as described for the second operation. Optionally, in some embodiments, the training data additionally includes physically generated ex situ metrology data, along with corresponding in situ chemical composition information. Regardless, a second machine learning model that uses OES sensors or other in situ chemical composition sensors effectively “learns” to correlate what an in situ wafer level optical sensor is able to learn, which is traceable to ex situ, postprocessing metrology results.

Relatively few wafers have both physically generated ex situ postprocessing metrology information and in situ chemical composition information. Therefore, the available physical data may be insufficient to train a second machine learning model. However, the first machine learning model extends the quantity of data having both types of information, thereby providing the second training set. As a consequence, a more robust second machine learning model may be trained. In certain embodiments, the training process trains the second machine learning model using virtually generated or inferred ex situ metrology data from at least about 20 wafers or from at least about 1000 wafers. As examples, the training the second machine learning model may be conducted using about 20 to 10,000 wafers.

A second machine learning model may be configured to receive in situ chemical composition data obtained while a process wafer is being processed and produce predicted ex situ metrology data and/or a wafer parameter value of the process wafer after processing is completed. A process wafer may be a wafer that is used in a commercial setting such as a wafer undergoing an integrated circuit fabrication operation. The resulting integrated circuits may be used in commercial and/or government applications.

Note that in situ chemical composition information may comprise detected intensity values for multiple wavelengths. In certain embodiments, the spectral range includes at least a fraction of the visible range, at least a fraction of the infrared range, at least a fraction of the ultraviolet range, or any combination thereof. In some embodiments, the in situ chemical composition information is not spectral; i.e., it includes intensity information for only one or a few wavelengths (e.g., emission wavelengths for an atomic species of interest).

In some cases, in situ chemical composition information comprises data collected over time (e.g., intensity versus time). In certain embodiments, in situ chemical composition data is collected over a period of at least about 1 seconds and/or over a period of at most about 50 seconds. In certain embodiments, in situ chemical composition information data is collected at a frequency of at least about 1 Hz and/or a frequency of at most about 50 Hz.

In situ chemical composition information may be collected using an optical emission spectrometer or other chemical detection unit disposed within process chamber or having access to a process chamber via one or more windows.

In some implementations, training the second machine learning model comprises performing an unsupervised or semi-supervised learning technique such as principal component analysis (time series) or generation of an autoencoder. The training process may reduce the large amount of in situ chemical composition sensor data. The reduction may involve transforming the raw in situ data to reduced dimensional latent space. In various embodiments, the second machine learning model is trained by a supervised learning process in which predicted metrology results serve as labels or tags.

In certain embodiments, a second machine learning model is trained using additional data beyond merely a combination of in situ chemical composition information and wafer structure parameter and/or ex situ metrology information. Such auxiliary data may include information about a preprocessed state of the wafer to be evaluated. As an example, the additional information may include metrology data (e.g., optical data from an integrated or standalone metrology system located upstream of the process chamber in question). As another example, the additional information may include information about one or more upstream processes performed on the wafer to be evaluated. Such information may include process conditions and/or other process constraints on an upstream process. As another example, the additional information may be from an in situ sensor such as a temperature sensor or plasma voltage/current sensor configured to obtain sensor readings in parallel with an in situ wafer level, optical sensor.

In some embodiments, training a second machine learning model is conducted in a way that selects certain dimensions and removes unselected dimensions from the latent space of the second machine learning model. Understand that a latent space may represent physical dimensions such as wavelength, intensity, and time in an abstract manner that may not directly translate back to the physical space. The dimensions of the latent space may be “selected” in the training operation based on their impact on the output of the model (e.g., wafer structure parameters such as CD, side-wall angle, and/or etch depth). The training may be conducted with a cost function that reduces the variation or error between predicted results (e.g., wafer structure parameters) and actual physical values in the training set. In some embodiments, the cost function may reduce latent loss by regularizing the latent dimensions into a Gaussian or other distribution. A goal of the training process may be to find a small but effective set of dimensions in the latent space of the model, which may be expressed in the form of mean and standard deviation vectors of, e.g., a Gaussian distribution. The process may be conducted iteratively by removing particular dimensions or groups of dimensions and determining whether the model still outputs sufficiently accurate representations of the incoming metrology data.

FIG. 3A is a table presenting an example of data sources and their use for training two models. The table also shows how information is applied to a trained second machine learning model. The training depicted in FIG. 3A condenses the above described training process into two “steps,” each associated with a different data source. The data source for “step 1” is used to generate a first machine learning model and the data source for “step 2” is used generate a second machine learning model. “Step 3” illustrates applying a trained second machine learning model (trained using the data source of “step 2”) to infer the conditions of wafers being processed such as production wafers.

In the table, the columns represent the three different data sources and their use (steps 1-3) and the rows represent the types of data or the sensors used to obtain that data. The bottom row provides examples of the data set sizes typically used for training.

In the illustrated embodiment, a first data source used to train a first machine learning model includes ex situ metrology data and in situ, on wafer optical metrology data (e.g., “LSR” metrology data). The ex situ metrology data is obtained from post processed wafers that have been fully or partially processed (e.g., etched). The on wafer optical metrology data is obtained during the processing of the wafers for which the ex situ metrology data has been obtained. The optical metrology data is provided as a function of time (e.g., as a time series) and wavelength. In other words, it has at least three dimensions: intensity, time, and wavelength (or other spectral information). The ex situ data is typically provided at a single time (post processing). It may be provided in the form of a typical metrology output (e.g., intensity a function of wavelength, position on the wafer, etc.). Alternatively, it may be interpreted and provided in the form of one or more wafer structure parameters (e.g., CD, etch depth, side-wall angle, etc.). For purposes of training a first machine learning model, the ex situ information serves as tags or targets.

In the illustrated embodiment, a second data source used to train a second machine learning model includes (a) inferred values derived from the on wafer, optical metrology data (as a function of time and wavelength), and (b) in situ OES signals obtained during processing of wafers comprising the data source. The OES signals may be provided as a function time (e.g., as a time series) and optionally wavelength. Note that the OES signals may be obtained from horizontally and/or vertically oriented sensors within a process chamber. Note also that the second data set may additionally include information obtained from one or more other sensors while wafers of the second data source are processed. If such information is included in training, the second machine learning model may be configured to receive both OES and other sensor information as inputs. Examples of information from other sensors includes pressure data, temperature data, plasma characteristics data (include V and/or I data), and process gas flow data. Like the OES signals, the information from other sensors may be provided as a function time (i.e., provided as a time series).

The inferred values may represent wafer structural parameters such as feature CD, depth, side-wall angle, and the like, or they may represent ex situ metrology values. These values are produced by providing time sequence on wafer optical metrology to the first machine learning model (produced using the first training data source). Note that the second data source is derived from a second set of wafers (that need not overlap with the set of wafers for the first training data source). Processing the second set of wafers produces (a) a time series of on wafer optical metrology values, (b) a time series of OES signals, and, optionally, (c) information from one or more other sensors (besides OES and optical metrology sensors). The OES and optical metrology signals may be provided in pairs, with each pair captured at the same time. However, the optical metrology signals are converted by the first machine learning model to on wafer structure parameter values (or ex situ metrology values) for the second training data set, which is used to train the second machine learning model. These wafer structure parameter values serve as tags or targets in the second training data set.

In some embodiments, the wafers used to produce the first data source are pilot wafers. In some embodiments, the wafers used to produce the second data source are pilot wafers or production wafers. In some implementations, a process chamber used to generate the second data source has both an OES sensor and an on wafer optical metrology sensor. In some implementations, these sensors share resources. For example, a single sensor may capture OES signals in a plasma process when a reflectometer light source is off and capture optical metrology signals when the light source is on.

The third column (third data source) of the table in FIG. 3A represents data captured when the second machine learning model is trained and deployed in an operating process chamber, such as a production device fabrication tool. The second machine learning model may analyze data from any number of wafers being processed. As explained, the second machine learning model may provide information about wafer structure parameters such as feature depth, CD, side-wall angle, etc.

FIG. 3B is a hybrid diagram showing models and training operations for first and second machine learning models. As depicted, ex situ metrology data 323 and in situ, on wafer, time series optical metrology data 321 (provided for in pairs for each wafer of set) used by a training process 325 for training a first machine learning model. The result of this training process is a first machine learning model 327. As depicted, subsequently, the in situ, on wafer, time series optical metrology data 331 (from a source different from that producing metrology data 321) is provided to the first machine learning model in a process 329. This process produces inferred time series of ex situ metrology values and/or wafer parameter values 333. In other words, the first machine learning model produces multiple ex situ metrology values and/or wafer parameter values from multiple in situ, on wafer, metrology data readings. This greatly expands the amount of data available to train a second machine learning model.

As depicted, the inferred data 333 is used together with OES time series data 335 to training the second machine learning model via a process 337. The result of this training is the second machine learning model 339. The OES data and inferred metrology or structure data 333 may be provided in pairs, time step by time step, to the training process 337.

FIG. 3C illustrates an example of a training method, implemented by training logic, for training a second machine learning model. As depicted, a training process 301 begins with an operation 303 that receives training data from a wafer set A. Each wafer of wafer set A may have (i) in situ collected wafer level optical information (from, e.g., a reflectometer in one or more process chambers for which the second machine learning model is being developed) and (ii) ex situ metrology data obtained from the wafer under consideration (a postprocessed wafer). Collectively, the pairs of in situ wafer level optical information and the ex situ metrology data for the various wafers of wafer set A comprise a first training set. As there may be relatively few wafers having ex situ metrology data available, wafer set A and correspondingly the first training set may be relatively small or sparse. In certain embodiments, the wafers of wafer set A do not have in situ collected chemical composition information of the type that is available with wafer set B, described below.

In an operation 305, the first training set is employed to train a first machine learning model. The resulting first machine learning model is configured to receive, as input, in situ wafer level optical information and provide, as output, predicted wafer structure parameter values and/or ex situ metrology data.

In an operation 307, the training logic receives information from a wafer set B. Each of wafer of wafer set B may have (i) in situ collected wafer level optical information (from, e.g., a reflectometer in a process chamber for which the second machine learning model is being developed) and (ii) in situ chemical composition data collected from the environment within one or more process chambers employed to process the wafers of wafer set B. As with the information from wafer set A, the information from wafer set B may be collected from one or more sensors (e.g., a reflectometer and an OES sensor) in one or more process chambers for which the second machine learning model is being developed. In certain embodiments, the wafers of wafer set B do not have ex situ metrology data of the type that is available with wafer set A. In certain embodiments, the number of wafers in wafer set B is substantially larger than the number of wafers in wafer set A; e.g., at least about 5-fold more wafers or at least about 10-fold more wafers. In some embodiments, at least some wafers from wafer set B are also present in wafer set A.

In an operation 309, the training logic applies the first machine learning model (trained in operation 305) to the in situ wafer level optical information of the wafers in wafer set B. This generates predicted wafer structure parameter values and/or metrology results for wafers of wafer set B. Collectively, the pairs of (i) in situ chemical composition data and (ii) predicted wafer structure and/or metrology results for the various wafers of wafer set B comprise a second training set.

In an operation 311, the training logic uses the second training set to train the second machine learning model. As indicated, a second machine learning model may be configured to receive, as input, in situ chemical composition information from a process chamber processing a wafer under consideration and provide, as output, predicted wafer metrology data and/or wafer structural information.

### Second Machine Learning Model Design and Operation

In certain embodiments, a second machine learning model is configured to receive the following input information: in situ chemical sensor data, and, optionally, additional in situ sensor data, preprocessing wafer metrology information, and/or pre-processing process conditions. The model may be configured to receive a time series of the in situ chemical sensor data.

In certain embodiments, the chemical composition information is obtained from an environment within the reaction chamber (e.g., a space between the wafer and process gas delivery element such as a showerhead). In certain embodiments, the environment contains a plasma, such as a plasma that facilitates reactions in the chamber. The chemical composition information may represent or reflect at least some information about the composition of one or more chemical species in a wafer, such as chemical species in one or more layers of the wafer. The chemical composition information may represent one or more byproducts of a reaction at the wafer surface or in the environment in which the wafer resides during processing. In certain embodiments, the chemical composition information is a spectroscopic signal, such as an emission spectrum of one or more species in the reaction chamber environment or on the wafer surface. Examples of sources of the chemical composition information are sensors configured to detect emissions of chemical species (e.g., OES sensors), sensors configured to detect scattering spectra of chemical species (e.g. Raman spectroscopy or certain x-ray spectroscopies) and sensors configured to detect radiation transmitted or absorbed by chemical species.

Note that the in situ data may be collected at multiple times, including up to near the end of a process under consideration. Thus, a model may employ a time series measurements (which may be in situ measurements) as an input or a single measurement that is obtained prior to, although possibly very close in time to, the predicted wafer structure parameter result.

In certain embodiments, a second machine learning model is configured to output predicted wafer surface properties, which may be provided as a “target” feature value (e.g., etch depth, pitch, side-wall angle, or critical dimension) or a metrology signal produced from such wafer surface properties. In some embodiments, a second machine learning model is configured to output chemical information about the wafer undergoing processing. For example, the second machine learning model may output information about when an etch process reaches a wafer layer that has a particular chemical composition. In some embodiments, a second machine learning model is configured to output one or more processing parameters as described herein, such as a time duration or a stop time of a processing operation. In certain embodiments, the second machine learning model is configured to output wafer surface parameter values at a time when the in situ chemical sensor data is collected or at a later time. In certain embodiments, the second machine learning model is configured to output a predicted time series of wafer structure parameter values.

In some embodiments, there is a delay in reading the chemical composition information from the wafer or process under consideration. An example of a process that has such delay is an absorption-based detection method. When a delay is present, the model may be trained in a way that accounts for the delay. For example, a predicted wafer condition may be for a time prior to the reading of sensed chemical composition information. Or the data provided to the model, may be preprocessed to adjust the time associated with the sensed information.

In some embodiments, the second machine learning model is configured to reduce the dimensionality of input data by using only certain features of the raw (sensed) chemical composition information. The raw data typically contains at least three-dimensional information: radiation intensity values at multiple wavelengths and over multiple time steps. In the second machine learning model, certain principal components or latent dimensions may represent relevant features of raw chemical composition information. The feature reduction or extraction associated with training or using a second machine learning model may reduce or remove parameters or contributions from parameters that are correlated or highly correlated.

In certain embodiments, the second machine learning model includes logic (integrated or separate) configured to control one or more knobs or process conditions in the process chamber under consideration. Examples of such knobs or process conditions include control mechanisms for controlling chamber pressure, a chamber component temperate, chamber plasma condition (e.g., plasma power, plasma frequency(ies), plasma pulse properties, plasma density, etc.), process time (e.g., for end point control), process gas flow rate and/or composition, etc.

As indicated, a second machine learning model may be implemented in many different forms. Examples include regularized linear models, support vector machines, decision trees, random forest models, gradient boosted trees, neural networks, autoencoders, linear combinations (e.g., a summation of weighted contributions of input parameter values), non-linear expressions (e.g., second or higher order polynomial expressions including input parameter values), look up tables, classification trees, dynamic time warping, similarity metric driven algorithms, pattern matching and classification, and variations of multivariate statistics (e.g., PCA, PLS).

In some implementations, the model is computationally efficient so that it can process in situ chemical composition signals in real time to determine a process condition (e.g., the end of an etch process) from the in situ information. In certain embodiments, the second machine learning model analyzes spectral information (for, e.g., endpoint assessment) in about 100 ms or less (from the time it receives input values such as optical emission measurements). In certain embodiments, the process control completes processing in about 20 ms or less. Such rapid processing may be employed, for example, in applications with critical step change requirements or in high etch rate processes (e.g., etch processes that complete in less than about a minute). In processes with many variations induced by the processing regime (such as in RF pulsing or gas pulsing) or when the wafer structure itself has a complicated structure (such as in stacks of alternating materials), such rapid processing may require efficient algorithms such as those described herein. The second machine learning model's execution time also depends on the type of algorithm used. In some implementations the model processes all or much of the time evolution of the spectral information from the beginning of the etch process to the current time. This may require a dimension reduction process such as principal component analysis (PCA) or partial least squares (PLS) or processing by an autoencoder. In some cases, a processing system implementing a second machine learning model may be configured with processing capabilities such as processors with large amounts of buffer space, multithreading, and/or multiple cores.

In certain embodiments, a second machine learning model is configured to predict a future time when the end point (or other condition) is met. Thus, for example, the second machine learning model may be configured to input current spectral data (or a time series of recent spectral data) and predict a time in the future when the condition is met. In such implementations, the model looks ahead to a future time when the condition is met rather than instantaneously determining that the condition is met.

In some implementations, a second machine learning model's result (output of a geometric parameter such as an etch depth corresponding to an etch endpoint) is provided with a “confidence.” The output may be given a low confidence if the model predicts a geometry outside the range of geometries used to generate or validate the model. For example, if the model determines that a feature being etched has a critical dimension that is narrower than that of any geometries used to generate the model, a predicted etch depth end point may be given a low confidence. Additionally, a prediction may be given a low confidence if the optical signals used as inputs are outside an expected range. In certain types of etch process, the signal variations from non-modeled factors influence the fit of the model and can reduce confidence. Examples of such signal variations include “noise” from illumination variations (lamp noise or laser noise), variations in hardware setup relative to those assumed in the model, etc. In probabilistic models, the confidence in a call may include a contribution from data used to develop such models (e.g., the amount of such data and variations in it).

In certain embodiments, the model uses an optical output signal over only a limited range of wavelengths (or other aspect of the optical signal). Using a selected range as a model input can require less computation, and therefore faster calculation, to determine an etch feature's geometry. It can also allow the result to be calculated without interference from correlated geometric parameters; for example, etch depth can be calculated without significant interference from input signals that strongly correlate with critical dimension. For example, a first wavelength range may strongly correlate with etch depth, while a different wavelength range may strongly correlate with critical dimension but only weakly correlate with etch depth. A process focusing on etch depth may, to avoid obscuring signal, use only optical signals in the first wavelength range.

Depending upon the chemical composition sensing tool used, the usable output signal may be constrained to a narrow range of a characteristic other than wavelength. For example, the used output signal may be limited to a specific polarization state.

In some examples, the selected wavelength range or other selected optical parameter range varies as a function of time during the etch process. In other words, the selected range or ranges of optical parameters varies from one time increment to another. This may provide an appropriate way to attack a problem when the spectral structure of the optical signal of interest varies from one time step to the next. For example, the center of a reflected intensity peak associated etch depth may change in wavelength over the period an etch process.

### Applications

As indicated, a second machine learning model may be used to control a fabrication operation in real time such as by determining, e.g., an etch or deposition endpoint. A second machine learning model may also be employed to enhance an understanding of how chamber conditions impact wafer structure parameters or metrology results such as post-process metrology results. This enables in situ metrology in real time to control process parameters like endpoint time and process knobs.

A second machine learning model may be used to control chamber-to-chamber matching. For example, two chambers may have different measured in situ parameters that are input to the same second machine learning model, which predicts different post processed wafer results. Recognizing the difference in these results, a manual or automatic adjustment can be made to the process conditions (e.g., via chamber control parameters) to one or both chambers in order to bring their operation into alignment.

In some embodiments, a second machine learning model may be employed in applications other than process control. As examples, a second machine learning model may be employed to design new processes, to diagnose actual or potential issues with a recipe and/or a fabrication tool component, or to provide analyses of component failures.

Often device fabrication tools of a particular type (e.g., a particular model of an inductively coupled plasma etcher) are deployed as a group or fleet at an IC fabrication facility (sometimes called a “fab”). In some embodiments, a machine learning model, such as a first or second machine learning model described herein, is provided for a fleet of fabrication tools. In some embodiments, such machine learning model is trained using data from the fleet. Regardless of how it is trained, the machine learning model may reliably predict wafer structure parameter information for all fabrication tools in the fleet. However, over time, one or more of the operational fabrication tools in the fleet may drift so that the machine learning model no longer accurately predicts wafer structure parameter information for the drifting fabrication tools. Drift may be caused by various effects including hardware changes caused by normal operation. Model performance monitoring and/or calibration may detect drift or its effect on the machine learning model's ability to predict wafer structure parameter information for a given fabrication tool. As an example, drift may be detected by comparing the model's predicted wafer structure parameter information to ex situ data from post processed wafers. Using this calibration, an offset or other correction may be determined for the machine learning model. Such offset may be applied to address drift on tool-by-tool basis; i.e., a separate correction may be applied for each fabrication tool in a fleet. In some embodiments, the machine learning model may be retrained using data from the fleet after one or more of its tools have drifted.

In certain embodiments, a fleet-level control or monitoring system comprises logic (e.g., software and/or hardware) configured to provide offsets, on a per process chamber basis, to predictions by a machine learning model of (i) ex situ metrology data of the process wafer after processing is completed, and/or (ii) one or more wafer structure parameter values of the process wafer at one or more times while the process wafer is being processed.

### Apparatus

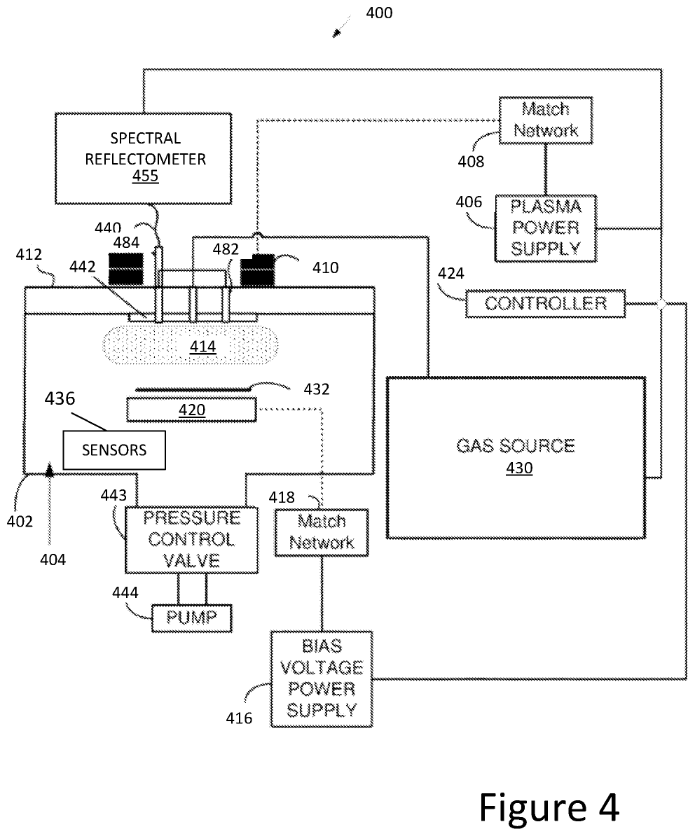

Many different reactor configurations are available for implementing the second machine learning model of the present disclosure. FIG. 4 schematically illustrates an example of a fabrication tool 400 (e.g., a plasma processing system) having both in situ reflectometry and in situ optical emission spectroscopy capabilities.

The fabrication tool 400 includes a plasma reactor 402 having a plasma processing confinement chamber 404. A plasma power supply 406, tuned by a match network 408, supplies power to a transformer-coupled-plasma (TCP) coil 410 located near a power transmission window 412 to create a plasma 414 in the plasma processing confinement chamber 404 by providing inductively coupled power. The TCP coil (upper power source) 410 may be configured to produce a uniform diffusion profile within the plasma processing confinement chamber 404. For example, the TCP coil 410 may be configured to generate a toroidal power distribution in the plasma 414. The power transmission window 412 is provided to separate the TCP coil 410 from the plasma processing confinement chamber 404 while allowing energy to pass from the TCP coil 410 to the plasma processing confinement chamber 404. A wafer bias voltage power supply 416 tuned by a match network 418 is configured to provides power to an electrode in the form of a substrate support 420 to set the bias voltage on the substrate 432 which is supported by the substrate support 420. A controller 424 is configured to set points for the plasma power supply 406, a gas source/gas source 430, and the wafer bias voltage power supply 416.

The plasma power supply 406 and the wafer bias voltage power supply 416 may be configured to operate at specific radio frequencies such as, for example, 13.56 MHZ, 27 MHz, 2 MHz, 60 MHz, 100 kHz, 2.54 GHz, or combinations thereof. Plasma power supply 406 and wafer bias voltage power supply 416 may be appropriately sized to supply a range of powers in order to achieve desired process performance. In addition, the TCP coil 410 and/or the substrate support 420 may be comprised of two or more sub-coils or sub-electrodes, which may be powered by a single power supply or powered by multiple power supplies.

The gas source 430 is in fluid connection with plasma processing confinement chamber 404 through gas inlets 482 in a shower head 442. The gas inlets 482 may be located in any location in the plasma processing confinement chamber 404 and may take any form for injecting gas. In certain embodiments, the gas inlet is configured to produce a “tunable” gas injection profile, which allows independent adjustment of the respective flow of the gases to multiple zones in the plasma process confinement chamber 404. The process gases and byproducts are removed from the plasma process confinement chamber 404 via a pressure control valve 443 and a pump 444, which also serve to maintain a particular pressure within the plasma processing confinement chamber 404. The gas source/gas supply mechanism 430 is controlled by the controller 424. A collimator housing 484 is connected to at least one gas inlet 482.

Tool 400 includes one or more in situ metrology devices. The metrology device(s) may include, as examples, a spectral reflectometer device 455 and sensors 436. Sensors 436 may include, as examples, one or more voltage and/or current sensors (e.g., VI probes), one or more optical emission spectroscopy sensors (OES), one or more sensors for measuring absorption spectra of plasma and/or gases present in chamber 404, one or more sensors for measuring plasma density, one or more sensors for measuring process gas, byproduct, and/or other gas concentrations in chamber 404, and other suitable sensors for monitoring process conditions and/or various indicia of wafer properties.

In certain embodiments, the controller 424 is configured to execute processing operations that utilize the spectral data collected by the spectral reflectometer 455 and/or other data reflecting process conditions or information about wafer 432 and/or the chamber environment collected by sensors such as in situ monitoring sensors 436, in order to process chamber information. Spectral data collected by device 455 may be collected at predefined intervals, such as at every predefined number of milliseconds, seconds, or some custom time setting.

Spectral reflectometer device 455 may, as an example, include components mounted within chamber 404 and components mounted outside of chamber 404. In some embodiments, spectral reflectometer device 455 includes an optical head inside of chamber 404, one or more light sources and light detectors outside of chamber 404, and an optical cable 440 or other component that optically connects the optical head to the light source(s) and detector(s). In one aspect, the spectral reflectometer device 455 has a collimator housing 484 that is connected to at least one gas inlet 482. Additionally, the collimator housing may be optically coupled, via optical cable 440, to the light source(s) and/or detector(s) of spectral reflectometer device 455. In this aspect, the optical cable 440 may include transmission optical fibers and receiving optical fibers. In other aspects, the optical cable 440 may include at least one optical fiber that conveys light from a light source in the spectral reflectometer device 455 and that also conveys light reflected off of the substrate 432. In one specific example, spectral reflectometer device 455 is configured to generate broadband light that is projected onto the surface of the wafer 432, while a detector in device 455 collects the spectral data associated with the reflected light from the surface of the substrate.

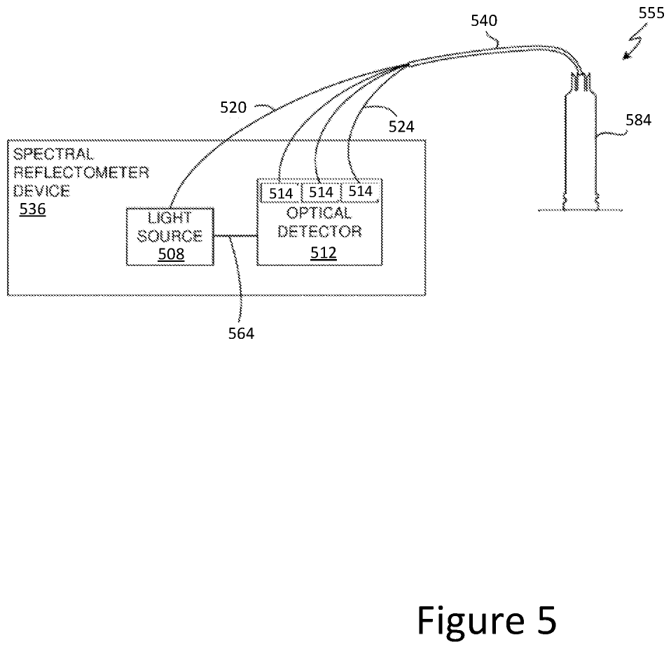

As indicated, data from an in situ reflectometer or similar apparatus may be employed to collect in situ, wafer level, optical information, which may be used to train a first machine learning model. FIG. 5 is a schematic view of an example of an in situ spectral reflectometer system 555. A spectral reflectometer device 536 comprises a light source 508 and an optical detector 512. The optical detector 512 may comprise one or more photodetectors 514. The fiber optic cable 540 is connected to the spectral reflectometer device. In this example, the optical cable 540 comprises transmission optical fibers 520 and receiving optical fibers 524. In this example each receiving optical fiber 524 is connected to an individual photodetector 514. In other embodiments a plurality of receiving optical fibers 524 may be connected to the same photodetector 514. In this example, the optical detector 512 is a two dimensional charge couple device (2-D CCD) array where an output from each receiving fiber 524 is detected by different regions of the 2-D CCD. For a spectral reflectometer system, the optical detector 512 provides output of intensity as a function of wavelength. This may be accomplished by using a prism or a filter that is able to separate out one or more wavelengths from the reflected light. Light may be directed from the light source 508 to the optical detector 512 through a fiber 564 to allow the monitoring of light source 508 variations over time to correct the signal and improve signal-to-noise ratio (SNR).

A collimator housing 584 includes a microlens array. A microlens array comprises a plurality of adjacent lenses. As an example, a 10 mm×10 mm microlens array may have at least 81 microlenses. The collimator housing 584 supports a collimator lens, which in this embodiment is a single lens that extends across a bore in the collimator housing 584. An optical path extends along the length of the collimator housing 584 from an end of the optical cable 540, through the microlens array and the collimator lens, so that the single collimator lens extends completely across the optical path.

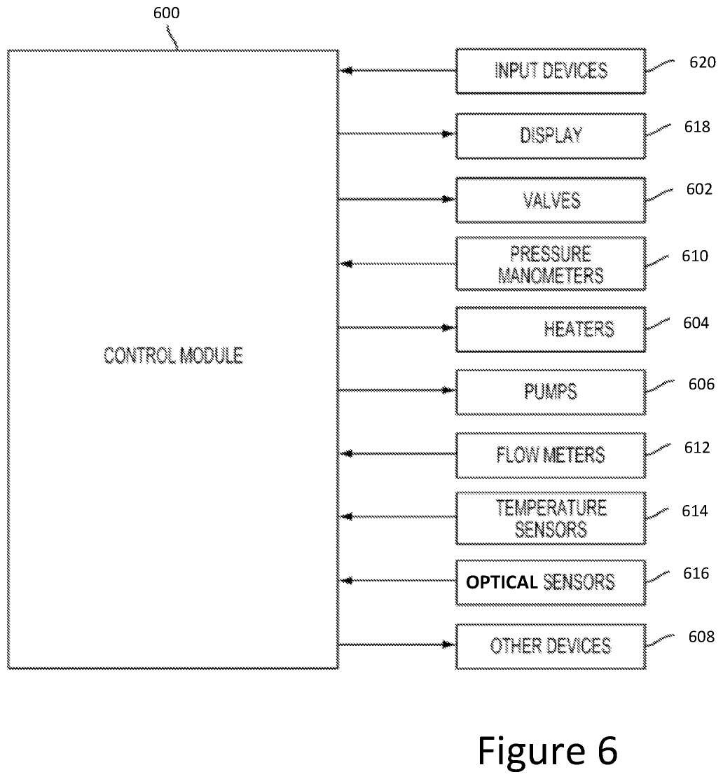

FIG. 6 shows a control module 600 for controlling the systems described above. For instance, the control module 600 may include a processor, memory and one or more interfaces. The control module 600 may be employed to control devices in the system based in part on sensed values. For example, only, the control module 600 may control one or more of valves 602, heaters 604, pumps 606, and other devices 608 based on the sensed values and other control parameters. The control module 600 receives the sensed values from, for example only, pressure manometers 610, flow meters 612, temperature sensors 614, and/or optical sensors 616 (e.g., an OES sensor). The control module 600 may also be employed to control process conditions during precursor delivery and deposition of the film and/or during etching processes. The control module 600 will typically include one or more memory devices and one or more processors.

The control module 600 may control activities of the precursor delivery system and deposition and/or etch apparatus. The control module 600 executes computer programs including sets of instructions for controlling process timing, delivery system temperature, pressure differentials across the filters, valve positions, mixture of gases, chamber pressure, chamber temperature, wafer temperature, RF power levels, wafer chuck or pedestal position, and other parameters of a particular process. The control module 600 may also monitor the pressure differential and automatically switch vapor precursor delivery from one or more paths to one or more other paths. Other computer programs stored on memory devices associated with the control module 600 may be employed in some embodiments.

There may be a user interface associated with the control module 600. The user interface may include a display 618 (e.g., a display screen and/or graphical software displays of the apparatus and/or process conditions), and user input devices 620 such as pointing devices, keyboards, touch screens, microphones, etc.

Computer programs for controlling delivery of precursor, deposition and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck.

Examples of sensors that may be monitored during deposition include, but are not limited to, mass flow control modules, pressure sensors such as the pressure manometers 610, and thermocouples located in delivery system, the pedestal or chuck (e.g., the temperature sensors 614). Appropriately programmed feedback and control algorithms (e.g., a second machine learning model as described herein) may be used with data from these sensors to maintain desired process conditions. The foregoing may be implemented in a single or multi-chamber semiconductor processing tool.

In some embodiments, the plasma may be monitored in situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

Any suitable chamber may be used to implement the disclosed embodiments. Example deposition apparatuses include, but are not limited to, process chambers in the ALTUSR product family and the VECTOR® product family, each available from Lam Research Corp., of Fremont, California. Example etch apparatuses include, but are not limited to, process chambers in the KIYOR product family, available from Lam Research Corp. Two or more of the stations, each configured to hold a wafer during processing, may perform the same functions in a deposition or etch system. Similarly, two or more stations may perform different functions. Each station can be designed or configured to perform a particular function/method as desired.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface. Signals for monitoring the process may be provided by analog and/or digital input connections of the system controller.

The signals for controlling the process are output on the analog and digital output connections of the deposition apparatus.

The system software may be designed or configured in many ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the deposition or modification of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, and any other semiconductor processing systems that may be associated or used in the fabrication and/or manufacturing of semiconductor wafers.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of producing a machine learning model, the method comprising:
(a) receiving a first training set generated from a first set of wafers, the first training set comprising (i) ex situ metrology data or wafer structure parameter values, obtained from the first set of wafers after the first set of wafers has been processed, and (ii) in situ wafer-level, optical sensor data obtained from the first set of wafers while the first set of wafers was being processed;
(b) training a first machine learning model using the first training set, wherein the first machine learning model is configured to receive in situ wafer-level optical sensor data generated from a wafer undergoing processing and predict wafer structure parameter values;
(c) using the first machine learning model to generate predicted wafer structure parameter values for a second set of wafers, wherein the second set of wafers has associated in situ chemical composition data and associated in situ wafer-level optical sensor data obtained while the second set of wafers was being processed; and
(d) training a second machine learning model using a second training set comprising (i) the predicted wafer structure parameter values from (c), and (ii) the associated in situ chemical composition data obtained while the second set of wafers was being processed, wherein the second machine learning model is configured to receive in situ chemical composition data for a process wafer being processed and predict wafer structure parameter values of the process wafer at one or more times while the process wafer is being processed or after processing is completed.

2. The method of claim 1, wherein wafers of the first set of wafers do not have associated chemical composition data.

3. The method of claim 1, wherein the ex situ metrology data is obtained from one or more standalone metrology tools.

4. The method of claim 3, wherein the standalone metrology tool is a CD-SAXS tool, a CD-SEM tool, or an optical metrology tool.

5. The method of claim 1, wherein the in situ wafer-level optical sensor data comprises optical intensity values at multiple wavelengths and multiple times.

6. The method of claim 1, wherein the in situ chemical composition data obtained while the second set of wafers was being processed is generated from an optical emission spectrometer.

7. The method of claim 1, wherein the second set of wafers does not have associated ex situ metrology data or wafer structure parameter values.

8. The method of claim 1, wherein the first set of wafers are pilot wafers.

9. The method of claim 1, wherein the first set of wafers was processed by an etch process.

10. The method of claim 1, wherein the second set of wafers are production wafers.

11. The method of claim 1, wherein the first set of wafers and second set of wafers were processed using the same type of fabrication tool.

12. The method of claim 11, wherein the second machine learning model is configured to predict the wafer structure parameter values for multiple different fabrications tools, which are all of the same type, in an IC fabrication facility.

13. The method of claim 1, wherein the first machine learning model is configured to produce a reduced dimensional representation of the in situ wafer-level optical sensor data obtained from the first set of wafers and/or perform feature extraction on in situ wafer-level optical sensor data obtained from the first set of wafers.

14. The method of claim 1, wherein the first machine learning model is configured to perform principal component analysis or utilizes a neural-network-based autoencoder.

15. The method of claim 1, wherein the second machine learning model is configured to reduce a dimensionality of the in situ chemical composition data and/or perform feature extraction on in situ chemical composition data.

16. The method of claim 1, wherein the second machine learning model is configured to indicate when an etch process has reached an end point.

17. The method of claim 1, wherein at least some wafers of the first of wafers are also in the second set of wafers.

18. The method of claim 1, wherein the wafer structure parameter values comprise an etch depth, a critical dimension, a side-wall angle, a repeating feature pitch, a layer thickness, a layer material property, or any combination thereof.

19. A computer program product comprising a computer readable medium on which are provided computer executable instructions for producing a machine learning model, the instructions comprising instructions configured to:
(a) receive a first training set generated from a first set of wafers, the first training set comprising (i) ex situ metrology data or wafer structure parameter values, obtained from the first set of wafers after the first set of wafers has been processed, and (ii) in situ wafer-level, optical sensor data obtained from the first set of wafers while the first set of wafers was being processed;
(b) train a first machine learning model using the first training set, wherein the first machine learning model is configured to receive in situ wafer-level optical sensor data generated from a wafer undergoing processing and predict wafer structure parameter values;
(c) use the first machine learning model to generate predicted wafer structure parameter values for a second set of wafers, wherein the second set of wafers has associated in situ chemical composition data and associated in situ wafer-level optical sensor data obtained while the second set of wafers was being processed; and
(d) train a second machine learning model using a second training set comprising (i) the predicted wafer structure parameter values from (c), and (ii) the associated in situ chemical composition data obtained while the second set of wafers was being processed, wherein the second machine learning model is configured to receive in situ chemical composition data for a process wafer being processed and predict wafer structure parameter values of the process wafer at one or more times while the process wafer is being processed or after processing is completed.

20. The computer program product of claim 19, wherein wafers of the first set of wafers do not have associated chemical composition data.

21. The computer program product of claim 19, wherein the ex situ metrology data is obtained from one or more standalone metrology tools.

22. The computer program product of claim 21, wherein the standalone metrology tool is a CD-SAXS tool, a CD-SEM tool, or an optical metrology tool.

23. The computer program product of claim 19, wherein the in situ wafer-level optical sensor data comprises optical intensity values at multiple wavelengths and multiple times.

24. The computer program product of claim 19, wherein the in situ chemical composition data obtained while the second set of wafers was being processed is generated from an optical emission spectrometer.

25. The computer program product of claim 19, wherein the second set of wafers does not have associated ex situ metrology data or wafer structure parameter values.

26. The computer program product of claim 19, wherein the first set of wafers are pilot wafers.

27. The computer program product of claim 19, wherein the first set of wafers was processed by an etch process.

28. The computer program product of claim 19, wherein the second set of wafers are production wafers.

29. The computer program product of claim 19, wherein the first set of wafers and second set of wafers was processed using the same type of fabrication tool.

30. The computer program product of claim 29, wherein the second machine learning model is configured to predict the wafer structure parameter values for multiple different fabrications tools, which are all of the same type, in an IC fabrication facility.

31.-46. (canceled)
